(19) United States
(12) Patent Application Publication
(10) Pub. No.: US 2026/0274654 A1
(43) Pub. Date: Sep. 17, 2026

(54) METHODS FOR FABRICATION OF MEMS DEVICES

(71) Applicant: Omnitron Sensors Inc., Los Angeles, CA (US)

(72) Inventor: Trent Huang, Los Angeles, CA (US)

(21) Appl. No.: 19/076,799

(22) Filed: Mar. 11, 2025

(51) Int. Cl. B81C 1/00; G02B 26/08

(52) U.S. Cl. CPC B81C 1/00658; G02B 26/0841; B81C 2201/0132; B81C 2201/0187

(57) ABSTRACT

A method for fabricating a micro-electromechanical system (MEMS) mirror device is disclosed. The mirror device has an in plane actuator directly under the mirror. A device layer, a handle layer, and a buried oxide layer between the handle layer and the device layer is provided. A top trench is created in a top surface of the device layer. An oxide layer is created over the top surface of the device layer and the top trench. The top of the device layer and the top trench is coated with a first polysilicon layer. The oxide layer of the top trench or the top of the device layer is etched away to create an isolated structure from the first polysilicon layer. Areas of the handle layer and the buried oxide layer are etched away to create a support structure attached to the isolated structure.

### TECHNICAL FIELD

The present disclosure relates generally to fabrication of MEMS structures. More particularly, aspects of this disclosure relate to a method of fabricating in plane and defined features for MEMS devices.

### BACKGROUND

Micro-electromechanical systems (MEMS) are microscopic devices incorporating both electronic devices and physical moving parts. A typical MEMS device is fabricated using integrated circuit techniques on a silicon wafer or wafers. The fabrication process creates the physical moving parts from fabricating different materials that may be deposited on and etched out of the substrate wafer.

MEMS have numerous applications such as in microphones, sensors, accelerometers, and light detection and ranging (LIDAR) systems. MEMS fabrication is intrinsically two dimensional to create physical structures on a substrate. Such structures may be moveable or even released for independent movement of other formed structures. Custom offsets of such structures add another dimension to MEMS topology and functionality. However, offsetting structures are often defined/limited by the dimensions of external tools and/or assembly accuracy from the fabrication process. It is desirable for such structures to have high strength to weight ratios, defined surfaces, and other features. However, fabrication of structures with such features is a challenge with existing fabrication techniques.

These are important differences/enhancements that are critical for MEMS mirrors. For example, such mirrors often have drive mechanisms to tilt and otherwise position the mirror on the device. Such drive mechanisms require precise fabrication that currently requires fabrication on the same plane as the mirror structure. For example, a comb based actuator may move a mirror structure based on connection of a rotor to a side of the mirror structure to move the mirror structure on a tether. However, the actuation mechanisms are not mechanically efficient when they are on the same plane as the mirror structure. Current fabrication methods do not include a simple method to fabricate drive mechanisms that are located under a mirror structure for more efficient actuation of the mirror.

Thus, there is a need for a MEMS fabrication process that allows for the efficient creation of aligned structures with a variety of well defined three-dimensional features. There is another need for a fabrication process that allows creation of isolated MEMS actuator and mirror structures. There is another need for a fabrication process that allows creation of releasable MEMS structures with relatively flat surfaces.

### SUMMARY

The term embodiment and like terms are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter; nor is it intended to be used in isolation to determine the scope of the claimed subject matter. The subject matter should be understood by reference to appropriate portions of the entire specification of this disclosure, any or all drawings and each claim.

One disclosed example is a method for fabricating a micro-electromechanical systems (MEMS) device. A device layer, a handle layer, and a buried oxide layer between the handle layer and the device layer are provided. A top trench is created in a top surface of the device layer. An oxide layer is created over the top surface of the device layer and the top trench. The top of the device layer and the top trench are coated with a first polysilicon layer. The oxide layer of the top trench or the top of the device layer to create an isolated structure from the first polysilicon layer. Areas of the handle layer and the buried oxide layer are etched away to create a support structure attached to the isolated structure.

In another disclosed implementation of the example method, the top trench is a deep isolation trench extending through the device layer to the buried oxide layer. The example method further includes removing material of the device layer along the deep isolation trench to release the isolated structure. In another disclosed implementation, the top trench is a shallow breakup trench shallower than a thickness of the device layer. In another disclosed implementation, the oxide layer is a sacrificial layer of a specified thickness to form a capacitive gap of the specified thickness between the isolated structure and the device layer. In another disclosed implementation, the example method includes depositing a patterned metal layer on the support structure. In another disclosed implementation, the support structure is a mirror, and the patterned metal layer is patterned as the mirror. In another disclosed implementation, the support structure is a bond pad, and the patterned metal layer is patterned as an electrical contact. In another disclosed implementation, the isolated structure is a comb of a rotor of a comb actuator. In another disclosed implementation, the device layer bordering the isolated structure is a comb of a stator of the comb actuator. In another disclosed implementation, the device layer and the handle layer are fabricated from a crystalline material selected from one of a group of silicon, Gallium Arsenide (GaAs), Indium Phosphide (InP), and Silicon Carbide (SiC).

Another disclosed example is a method of fabricating a micro-electromechanical systems (MEMS) mirror. An isolation trench is etched in a device layer formed on a buried oxide layer, and a handle layer. A plurality of finger defining trenches are etched in the device layer. The plurality of finger defining trenches are parallel to the isolation trench. An oxide layer is grown to fill the isolation trench and coat sides of the finger defining trenches. A polysilicon layer is grown to fill the finger defining trenches. The oxide layer coating sides of the finger defining trenches and the isolation trench are removed to create a plurality of polysilicon fingers separated by a gap from a plurality of fingers of the device layer. Areas of the handle layer and the buried oxide layer are etched away to define a support structure under the finger defining trenches. The oxide layer over the isolation trench is etched away to release the support structure and the finger defining trenches. A surface of the support structure is metalized to form a mirror surface.

In another disclosed implementation of the example method, the device layer between the finger defining trenches form combs of a rotor of a comb actuator. In another disclosed implementation, the plurality of polysilicon fingers bordering the finger defining trenches form combs of a stator of the comb actuator. In another disclosed implementation, the example method further includes forming a bond pad as part of a polysilicon conductor strip connected to the stator; and forming part of the patterned metal layer as an electrical contact on the bond pad. In another disclosed implementation, the example method further includes isolating a stator base on the device layer. A hinge structure coupled to the stator base is formed. The stator base and the combs are displaced at an angle on the hinge structure to offset the combs of the stator from the combs of the rotor at the angle. In another disclosed implementation, the device layer and the handle layer are fabricated from a crystalline material selected from one of a group of silicon, Gallium Arsenide (GaAs), Indium Phosphide (InP), and Silicon Carbide (SiC).

Another disclosed example is a micro-electromechanical system (MEMS) device including an electrostatic actuator having a stator and a rotor. The device includes a moveable structure having a bottom area coupled to the rotor. The actuator is positioned under the moveable structure. A base supports the stator. A hinge is coupled between the base and the moveable structure. The actuator moves the moveable structure on the hinge.

In another disclosed implementation of the example device, the moveable structure is a mirror. In another implementation, the device includes another electrostatic actuator having a stator and a rotor coupled to the bottom area of the moveable structure. The another electrostatic actuator is positioned under the moveable structure. Power is supplied to either actuator to move the moveable structure on the hinge. In another implementation, the stator is displaced at an angle from a planar surface of the base.

### BRIEF DESCRIPTION OF THE DRAWINGS

The disclosure will be better understood from the following description of exemplary embodiments together with reference to the accompanying drawings, in which:

FIG. 1A is a perspective view of a completed MEMS mirror device with various example three dimensional structures produced by the example fabrication method;

FIG. 1B is a perspective view of the MEMS mirror device in FIG. 1A in an actuated position relative to the view in FIG. 1A;

FIG. 1C is a see-through perspective view of the MEMS mirror device in an actuated position;

FIG. 1D is a top see-through view of the MEMS mirror device in FIG. 1A;

FIG. 1E is a perspective side view of the MEMS mirror device in FIG. 1A when one of the actuators is activated;

FIGS. 2A-2D are a series of processing diagrams for an in plane isolation method to form in plane isolation features and structures of the device in FIG. 1A;

FIGS. 3A-3C are a series of processing diagrams for an alternate in plane isolation method to form in plane isolation features and structures of the device in FIG. 1A;

FIGS. 4A-4C are a series of processing diagrams for forming the basic features and structures for the actuators and the mirror in the device in FIG. 1A;

FIGS. 5A-5E are a series of processing diagrams for forming the features and structures for the actuators and mirror in the device in FIG. 1A;

FIG. 6A is a see-through perspective view of another example MEMS mirror device that includes offset stators to enhance the movement range of the mirror structure; and

FIG. 6B is a side see-through perspective view of the example MEMS mirror device in FIG. 6A that includes offset stators to enhance the movement range of the mirror structure.

The present disclosure is susceptible to various modifications and alternative forms. Some representative embodiments have been shown by way of example in the drawings and will be described in detail herein. It should be understood, however, that the invention is not intended to be limited to the particular forms disclosed. Rather, the disclosure is to cover all modifications, equivalents, and alternatives falling within the spirit and scope of the invention as defined by the appended claims.

### DETAILED DESCRIPTION OF THE ILLUSTRATED EMBODIMENTS

The present inventions can be embodied in many different forms. Representative embodiments are shown in the drawings, and will herein be described in detail. The present disclosure is an example or illustration of the principles of the present disclosure, and is not intended to limit the broad aspects of the disclosure to the embodiments illustrated. To that extent, elements and limitations that are disclosed, for example, in the Abstract, Summary, and Detailed Description sections, but not explicitly set forth in the claims, should not be incorporated into the claims, singly or collectively, by implication, inference, or otherwise. For purposes of the present detailed description, unless specifically disclaimed, the singular includes the plural and vice versa; and the word “including” means “including without limitation.” Moreover, words of approximation, such as “about,” “almost,” “substantially,” “approximately,” and the like, can be used herein to mean “at,” “near,” or “nearly at,” or “within 3-5% of,” or “within acceptable manufacturing tolerances,” or any logical combination thereof, for example.

The present disclosure is directed toward fabrication processes for producing a MEMS device that allows for released structures with complex topologies. The process involves a substrate with a device layer and a handle layer. The process involves etching trenches, providing oxide coatings, formation of polysilicon structures, and selective etching away of the oxide coatings on the device layer. Various areas of the handle layer are etched away to produce released structures with well-defined features from the processing of the device layer. The process allows for in plane isolation of features in the fabrication process. Through vias with in plane isolation fabricated in the same step. The process also allows for structures with engineered stiffness distribution for optimal strength/mass ratio. The process also allows for electrically isolated MEMS structures.

The example process allows the fabrication of high aspect ratio silicon and poly structures such as comb structures that may be located underneath a device such as a mirror. This offers superior fill ratio for the mirror device as well as better performance parameters such as allowing higher resonant frequencies and lower required total chip areas. The example process allows a higher fill ratio for the formation of the features since the areal efficiency is better and a comb structure such as an actuator underneath a mirror helps stiffen up the mirror device without adding too much mass to the device.

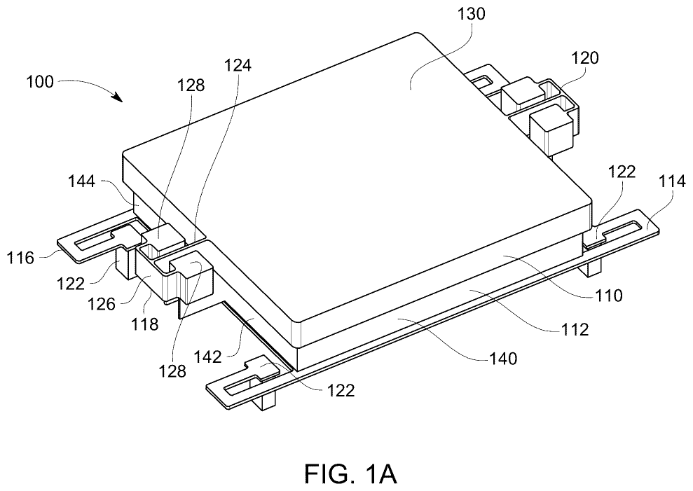

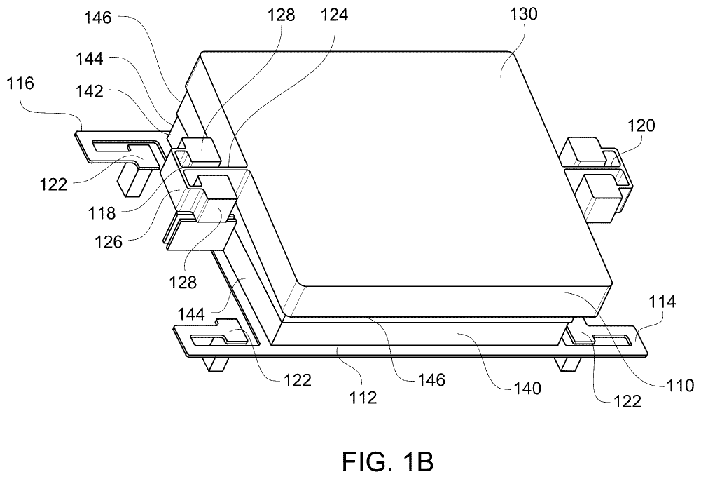

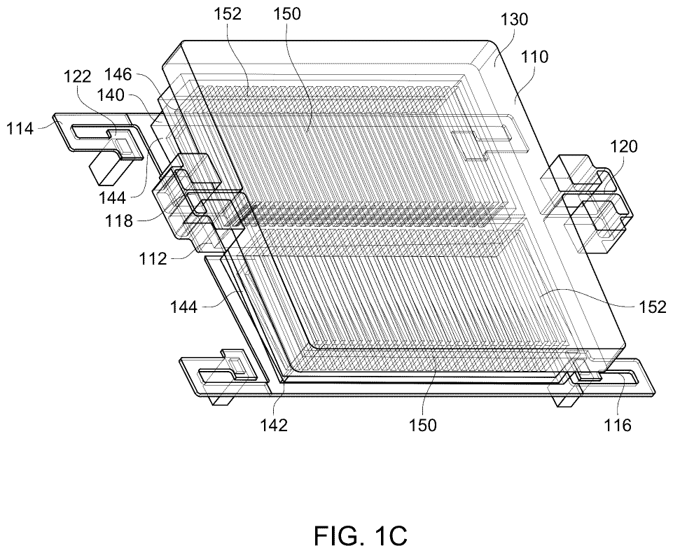

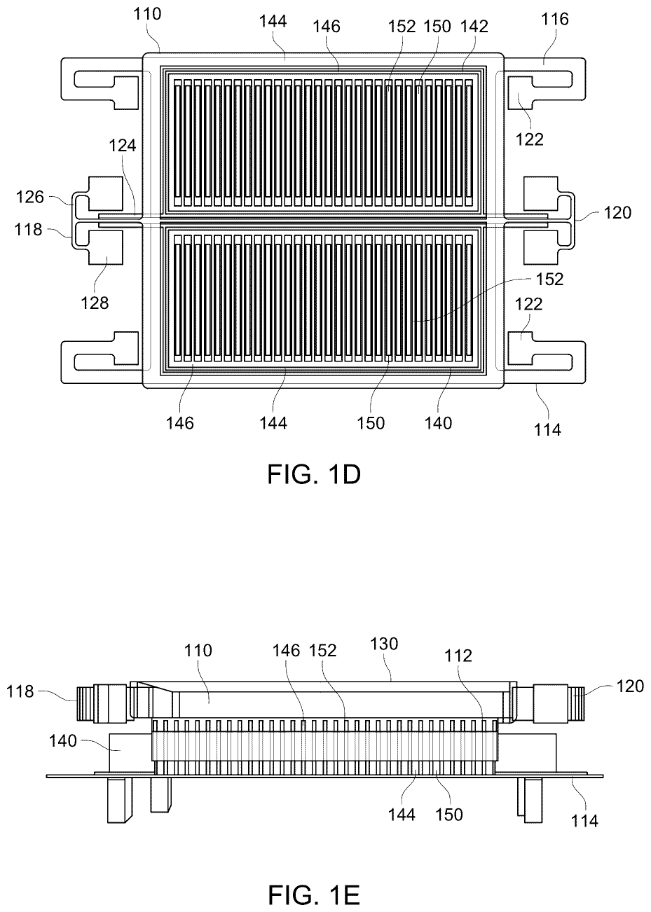

FIG. 1A shows a perspective view of a MEMS mirror device 100 with a mirror structure 110 and a comb-based actuator mechanism 112. FIG. 1B is a perspective view of the mirror structure 110 in an actuated position from the actuator mechanism 112. FIG. 1C is a see-through perspective view of the MEMS mirror device 100 with the mirror structure 110 in an actuated position. FIG. 1D is a top see-through view of the MEMS mirror device 100. FIG. 1E is a perspective side view of the MEMS mirror device when the mirror structure 110 is actuated. In this example, the MEMS mirror device 100 is a moveable mirror device for applications such as a LIDAR based system with structures such as actuators to tilt the mirror structure 110 as well as other releasable and in plane features and structures. In this example, the mirror structure 110 has a reflective layer that may be a metallic coating layer formed on a flat top surface. The mirror structure 110 may be tilted at different angles via the actuator mechanism 112 that may be used in optical applications such as LiDAR. In this example, the device 100 is part of a light detection and ranging (LiDAR) beam steering apparatus such as autonomous driving, robotics, and biomedical sensing. Other LiDAR applications may use the principles described here. In addition, high performance MEMS scanning devices may be produced by the example fabrication techniques. Such high performance scanning devices may be used in applications such as satellite communication, pollution and emission monitoring, 3-D printing, that may require a relatively large area mirror and linear, high resolution feedback for better performance.

The example fabrication methods allow the formation of the comb-based actuator mechanism 112 under the mirror structure 110. The positioning of the actuator mechanism 112 directly under the mirror structure 110 allows for efficient use of chip area with better mechanical performance since the comb structures enhance the out-of-plane stiffness of the mirror structure 110 without adding excessive mass. The mirror structure 110 is a torsionally driven one-dimensional mirror with comb drives in the actuator mechanism 112 embedded underneath the mirror structure 110. Thus, the actuator mechanism 112 is in planar alignment with the mirror structure 110, thus conserving horizontal surface area on a chip holding the MEMS mirror device 100. The MEMS mirror device 100 includes two conductor strips 114 and 116 with pads to allow connection to electrical contacts to power the actuator mechanism 112. The conductor strips 114 and 116 also function as flexures to allow movement of actuator mechanism 112. Torsional anchor structures 118 and 120 are attached to the sides of the mirror structure 110 that allow the mirror structure 110 to rotate along the axis between the torsional support structures 118 and 120 that may be twisted to allow this motion. Each of the anchor structures 118 and 120 include a flexure 124 that is coupled to a T-shaped structure 126 with anchor blocks 128. The anchor blocks 128 may be attached to a base structure. The conductor strips 114 and 116 include pads 122 that allow electrical connections to provide power to the actuator mechanism 112. Anchor blocks are formed under the pads 122 to allow attachment to a base structure. The mirror structure 110 has a top surface 130 that constitutes a metallic reflective coating that serves as the mirror.

The example actuator mechanism 112 includes two comb-based actuators 140 and 142. Each of the actuators 140 and 142 includes a respective lower stator 144 and an upper rotor 146. In this example, the two rotors 146 are attached to the bottom of the mirror structure 110 opposite the top mirror surface 130. Thus, when one of the rotors 146 moves relative to the respective stator 144, the mirror structure 110 may be twisted and thus moved to different angles relative to axis between the torsional structures 118 and 120. The rotor 146 in this example is suspended via a spring from the base of the device. The spring may be torsional, which will provide rotation or translational, which will provide translation of force. The force generated by the rotor 146 creates a torque in reference to supporting springs that connect the rotor 146 and or the mirror structure 110 to the base structure of the device. The rotation or displacement of the rotor 146 in reference to the stator 144 may be realized by capacitive force created between the stator 144 and the rotor 146 when power is supplied to the stator 144. The stator 144 may be either fixed or offset to create a starting relative displacement to help with the subsequent sensing/actuation. The lower stators 144 have a main body with a series of fine comb teeth 150. The corresponding rotors 146 have a main body that have a series of fine comb teeth 152.

When the rotors 146 are lowered into the respective stators 144 by applying current to create electrostatic attractive force as shown in FIG. 1A, the teeth 152 of the rotors 146 interlace with the teeth 150 of the stator 144. Thus, each of the comb teeth 150 of the lower stator 144 are in proximity with corresponding comb teeth 152 of the upper rotor 146. The example process described below allows fabricating the comb features to allow electrostatic force to be applied to displace the rotors 146 relative to the stators 144 by applying electrostatic force to the comb teeth 150 of the stators 144. This creates an attractive force with the comb teeth 152 of the rotor 146 causing displacement of the rotor 146 into the stator 144. As half of the mirror structure 110 is attached to the rotor 144, one side of the mirror structure 110 is pulled down causing twisting around the torsional structures 118 and 120. Thus, the mirror structure 110 may be tilted by activating one of the actuators 140 or 142 to pull the respective rotor 146 to the stator 144. For example, FIG. 1C shows power applied to the stator 144 of the actuator 142, causing the rotor 146 to be attracted to the stator 142. This twists the mirror structure 110 around the torsional structures 118 and 120. Power may be applied to the stator 144 of the actuator 140 to rotate the mirror structure 110 in the opposite direction.

The stators 144 may be either fixed or displaced with a designed offset by an angle or by a translational offset. Once displaced, the stator remains virtually stationary. In this example, the stators 144 are fixed to the base and thus are aligned planarly under the area of the mirror structure.

In this example, the main body of the rotors 146 is fabricated initially from a crystalline substrate such as crystalline silicon. The comb teeth 152 of the rotors 146 are formed by etching trenches to define the teeth 152 in the crystalline silicon as will be described herein. The comb teeth 150 of the stators 144 are formed by coating the trenches with thermal oxide and then filling the trenches by growing polysilicon to form the comb teeth 150 as will be explained herein. The teeth 152 are released from the initial substrate as will be explained below, which allows the movement of the rotors 146. Another layer of polysilicon over the trenches forms the main body and other features of the stators 144. Once the thermal oxide is etched away, the gaps are formed between the comb teeth 150 of the stators 144 and the comb teeth 152 of the rotors 146.

The gaps between the comb teeth 150 and 152 may be defined precisely by the example process to form a capacitor for the operation of the actuator mechanism 112. The comb teeth 150 and take advantage of the precision features that may be produced by the example fabrication methods. The example process creates a super uniform gap between the comb teeth 150 and 152 with a high aspect ratio.

The comb drive actuators 140 and 142 of the actuator mechanism 112 move in plane and out of plane e.g., back and forth, or up and down. One set of combs such as the comb teeth 150 for the stators 144 of the actuator 140 is fabricated from silicon while the other set of combs such as the comb teeth 152 for the corresponding rotor 146 of the actuator 140 is polysilicon but the example process allows small gaps to be formed on ends. This is superior to known methods of pulling out material from the trenches to define the structures.

There are separate, matching comb electrodes beneath the comb drives attached to the mirror. These electrodes may be displaced and locked mechanically to create an offset needed to actuate the mirror. The teeth 150 and 152 of the respective comb drive actuators 140 and 142 have highly uniform surfaces for maximizing capacitance that are fabricated according to the techniques explained below. The comb structures in the actuators 140 and 142 may also have co-existing tall/thin and flat/thin structures that are preferred for comb drive actuators.

As will be explained, the released structures such as the mirror structure 110 and the rotors 146 may have complex topologies through the processes described below. The released structures with a high aspect ratio may be fabricated in both silicon and polysilicon. Released structures with a very low aspect ratio may be fabricated from polysilicon. The process may produce released structures having a low aspect ratio in silicon for large, flat structures such as the mirror structure 110. The process allows engineered stiffness distribution for optimal strength/mass ratio in a structure. The device 100 allows low temperature, hermetically sealed package solution with feedthroughs to the isolated devices. As the actuator mechanism 112 is fabricated in line with the mirror structure, the chip area adjacent the mirror structure may be used for other structures. Further, the positioning of the actuators directly under the mirror structure 110 requires less energy to actuate the mirror structure 110. The teeth 152 of the rotors 146 also provide a light weight support structure for the mirror structure 110 allowing relatively larger surface areas of the mirror surface of the structure 110.

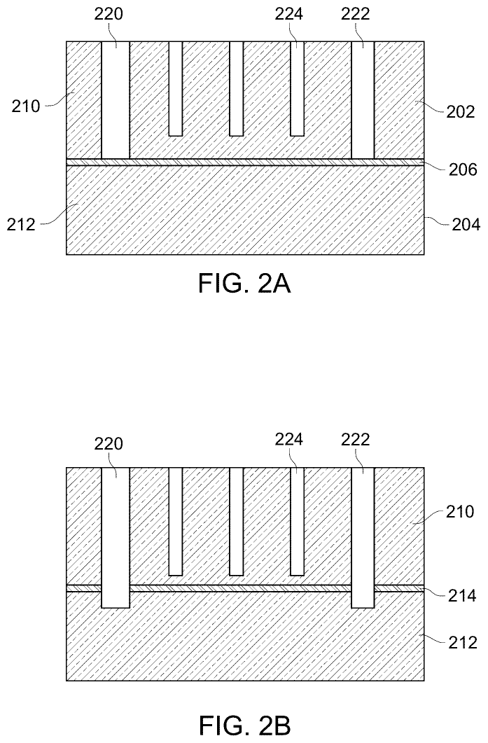

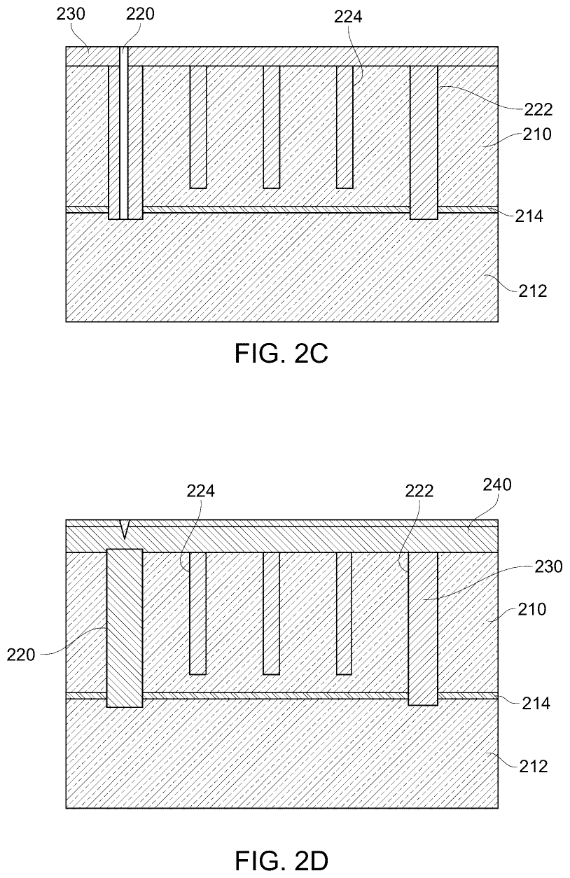

FIGS. 2A-2C show the steps of an example fabrication process to produce in plane isolation of structures in a MEMS device 100. In FIG. 2A, the process begins with fabricating a device wafer 202 and a handle wafer 204 that form a respective device layer 210 and handle layer 212. A buried oxide layer 214 is formed between the device wafer 202 and the handle wafer 204. There is no requirement for the thickness (t_{box}) of the buried oxide (BOX) layer 214. In this example, the device wafer 202 is typically 100-300 μm thick (h_{d}) and has a doping level sufficiently high to reduce resistance in the silicon which may negatively impact final device speed. Of course other crystalline materials such as Gallium Arsenide (GaAs), Indium Phosphide (InP), and Silicon Carbide (SiC) that achieve the same/similar topologies may be used for either of the wafers 202 and 204. There is no requirement on thickness (hₕ) for the handle wafer 204. Moderate to high doping levels are preferred since part of the handle wafer 204 with be used to direct signals out of the package with through wafer vias. The height may be dictated by the mechanical characteristics of the structure in handle layer. Thus, if the designer needs a more compliant structure realized in the handle layer within a small area, a thinner handle layer may be used.

FIG. 2A shows initial etching of two types of trenches in the device layer 210. In this example, two deep isolated trenches 220 and 222 are etched through the thickness of the device wafer 202 to the box layer 214. Thus, the deep isolated trenches (width: wᵢₛₒ, depth: hᵢₛₒ=h_{d}) go through the entire thickness of the device layer 210. A shallow “breakup” trench 224 (width: w_{b}, depth: h_{b}<<h_{d}) is formed to be shallower than thickness of the device layer 210. The shallow trench will later be used to either add a break or to provide in plane electrical isolation for the thin feature. The breakup trenches 224 are used to physically break up movable structures in shallow areas (depth h₁). In this example, typical values for the isolated trenches are wᵢₛₒ~5-10 μm; and w_{b}~0.5-2 μm. The deep trenches 220 and 222 may be etched to a depth that goes through the box layer 214 and extends to the handle layer 212 as shown in FIG. 2B.

FIG. 2C shows the deposition of a first layer of polysilicon 230 on the surface of the device layer 210. As shown in FIG. 2C, the polysilicon 230 fills the shallow trenches 224. The polysilicon 230 is grown to coat the sides of the deep trench 220 to serve as a conductive conduit. The polysilicon 230 is grown to fill all of the deep trench 222 to serve as a conductive conduit. Since the deep trenches 220 and 222 extend through the box layer 214, the polysilicon layer 230 contacts the handle layer 212. Thus, the thickness of the polysilicon, t_{poly1}>~0.5*wᵢₛₒ in this example. The polysilicon layer 230 needs to highly doped (e.g., doping level is greater than 1E17-20/cm³ or higher) for conductive vias formed through the device wafer 202. Such doping requirements are not needed for trench isolation purposes.

FIG. 2D shows the growth of a first silicon oxide layer 240 on the exposed surfaces of the device layer 210. The first silicon oxide layer 240 covers the filled trenches 224 and 222. In this example, the silicon oxide layer 240 fills the space between the polysilicon 230 on the sides of the trench 220 as well as oxidizes the polysilicon filling the trench 222.

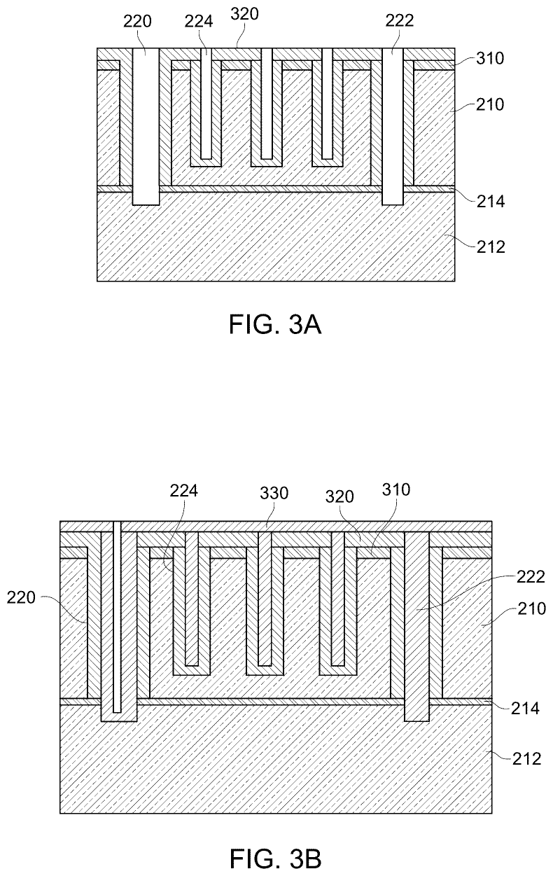

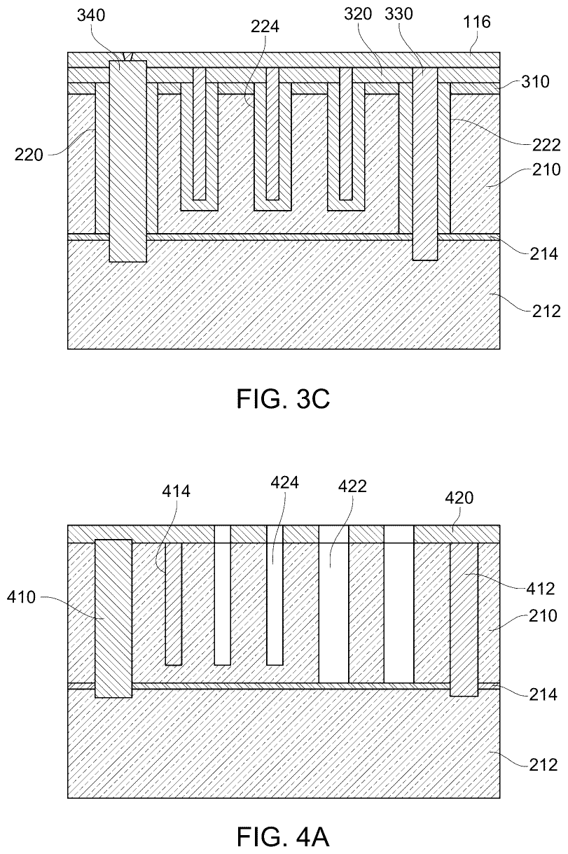

FIG. 3A-3D shows an alternative method of providing in plane isolation based on the trenches 220, 222 and 224 formed as shown in FIGS. 2A-2B. FIG. 3A shows the growth of a silicon oxide layer 310 that is grown prior to forming the trenches 220, 222, and 224. After the trenches 220, 222, and 224 are formed in the device layer 210, another oxide layer 320 is formed. The second oxide layer 320 is formed from the device layer 210 on the sides of the shallow trenches 224 as well as the deep trenches 220 and 222.

FIG. 3B shows the deposition of a first polysilicon layer 330. The polysilicon layer 330 fills the break up trenches 224. The polysilicon layer 330 fills the deep trench 222. The polysilicon layer 330 coats the sides of the other deep trench 220.

FIG. 3C shows the growth of a second silicon oxide layer 340 on the exposed surfaces of the device layer 210. The second silicon oxide layer 340 covers the filled trenches 224 and 222. In this example, the second silicon oxide layer 340 fills the space between the polysilicon 330 on the sides of the deep trench 220 as well as oxidizes the polysilicon 330 filling the deep trench 222.

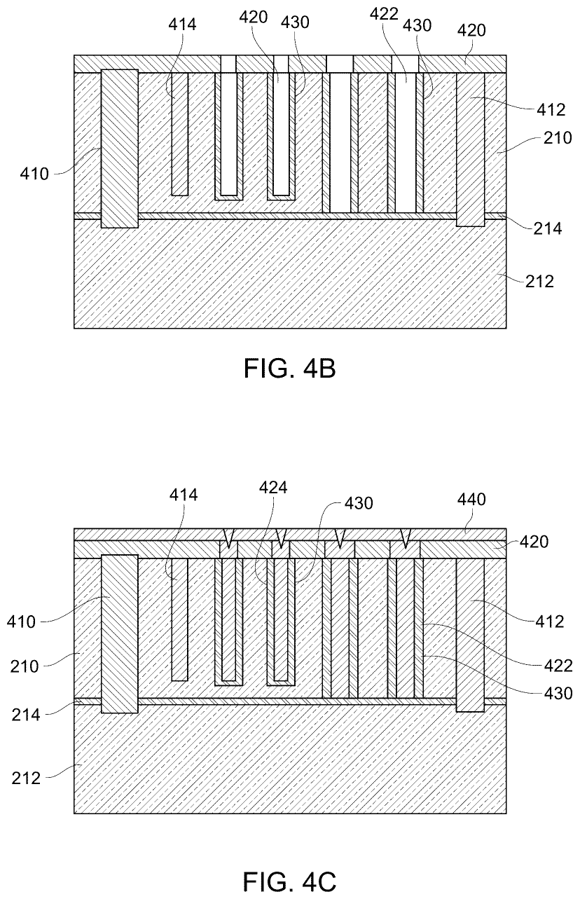

The top surface of the planar silicon oxide layer 340 may be smoothed over by performing an optional chemical mechanical planarization (CMP) process prior to forming the remaining structures in the device 100 in FIG. 1A. FIGS. 4A-4C show the process of creating the basic features and structures of the actuators 140 and 142 of the mirror device 100 in FIG. 1A after the creation of the in plane features and structures. FIG. 4A shows a different area of the features and structures formed in the device layer 210, handle layer 212, and buried oxide layer 214 from the wafers 202 and 204 in FIG. 2A or 3A. Thus, the above described processes in FIG. 2A-2D or 3A-3C may be used to create a first in plane structure 410 of oxidized polysilicon in the deep trench 220, a second in plane structure 412 of polysilicon in the deep trench 222, and a third in plane structure 414 in the shallow trench 224. A layer of silicon oxide 420 covers the device layer 210 from the previous processing steps.

In this example, a series of trenches are etched through the silicon oxide layer 420 and the device layer 210 by patterning the oxide layer 420. Thus, deep trenches 422 that are etched to the buried oxide layer 214 and shallow trenches 424 may be etched at a shallower depth in the device layer 210 short of the buried oxide layer 214.

FIG. 4B shows the oxidation of the sidewalls of the trenches 422 and 424 via a layer of silicon oxide 430 that is grown on the sides of the trenches 422 and 424. After growing the silicon oxide layer 430, the trenches 422 and 424 are then filled via the deposition of a polysilicon layer 440 as shown in FIG. 4C. The polysilicon layer 440 fills the areas between the sidewalls of the silicon oxide layer 430 in the trenches 422 and 424. The top surface of the polysilicon layer 440 may be smoothed over by performing an optional chemical mechanical planarization (CMP) process.

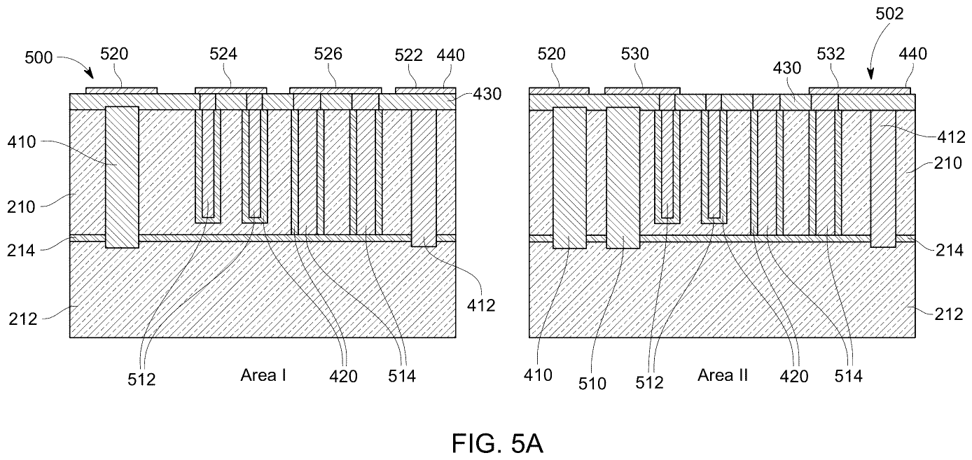

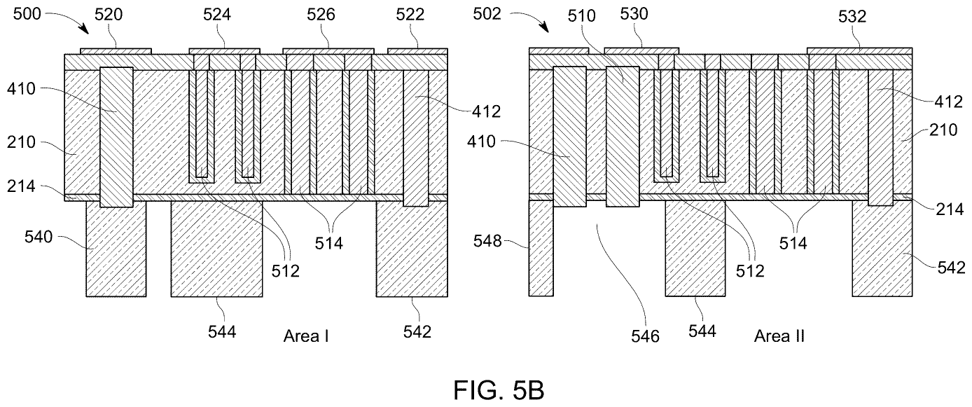

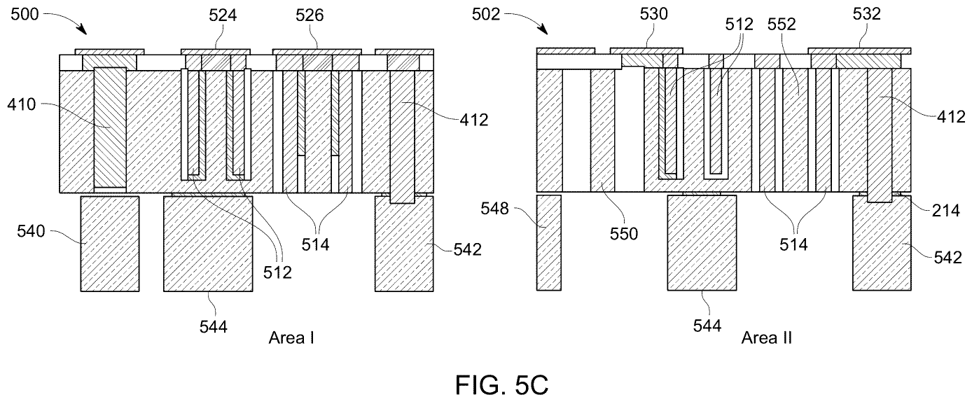

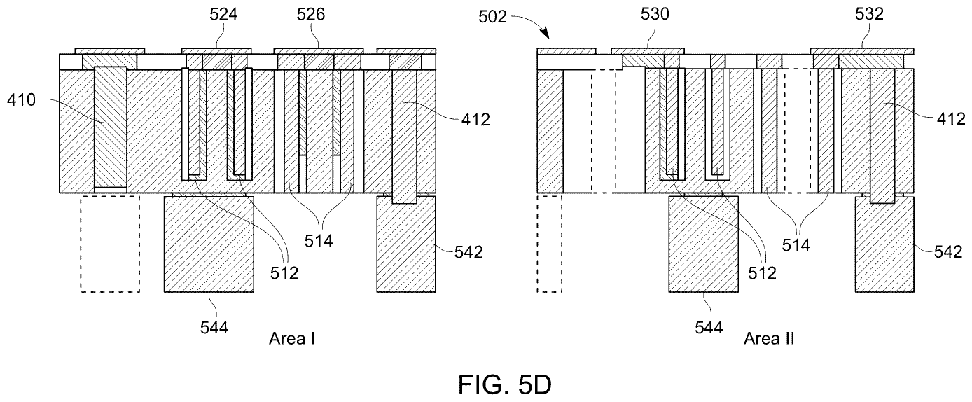

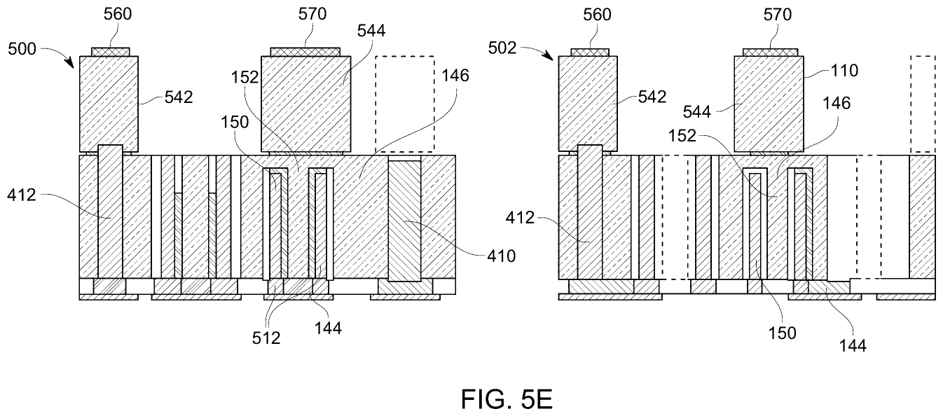

FIGS. 5A-5E show the stages of the example method to form the features and structures of the mirror structure 110 and release the mirror structure and the stators of the actuators 140 and 142 of the device 100. As shown in FIGS. 5A-5E the mirror structure 110 may be fabricated in alignment with the actuators 140 and 142 to allow the actuators 140 and 142 to be positioned directly under the mirror structure 110 via the back etching of the handle layer 212. FIGS. 5A-5E show two different areas 500 and 502 of the device layer 210 and the handle layer 212 for purposes of illustrating different types of structures that may be fabricated with the example fabrication method. In this example, the areas 500 and 502 include in plane features such as in plane structures 410 and 412 formed through the process in FIG. 2A-2D or 3A-3C. Another example in plane feature 510 formed via the methods described herein is shown in the area 502. The in plane feature 510 defines an isolation trench that will be used to isolate different structures in the area 502. A set of shallow structures 512 and a set of deep structures 514 are also shown as formed by the process in FIGS. 4A-4D.

As shown in FIG. 5A, a mask may be applied to etch away parts of the polysilicon layer 440 to create support contact pads 520 and 522 for the corresponding in plane structures 410 and 412. Other structures 524 and 526 may be defined by the etched polysilicon layer 440 for joining the respective structures 512 in the shallow trenches 424 or the structures 514 in the deep trenches 422 in the area 500. As shown in FIG. 5A, the area 502 includes a contact pad 530 for joining the in plane feature 510 to the structure 410 that is formed from the polysilicon layer 440. Another contact pad 532 formed in the polysilicon layer 440 joins the in plane structure 412 to one of the structures 514.

The silicon in the handle layer 212 is then patterned by a backside etching process to form the mirror structure that are in line with the actuators formed from the features and structures in the device layer 210. A pattern mask is applied and results in etching away parts of the handle layer 212 in both areas 500 and 502 as shown in FIG. 5B. As shown in FIG. 5B, in the area 500, a sacrificial block 540 in contact with the in plane structure 410 is created from etching away parts of the handle layer 212. A bond pad support structure 542 is created from etching away parts of the handle layer 212. A mirror support structure 544 is defined on the box layer 214 via the pattern etching. In the area 502, a region 546 is defined by etching away the handle layer 212 to the box layer 214 to expose the structures 410 and 510 from the back side. The region 546 is thus defined by the sides of the mirror support structure 544 and a sacrificial block 548.

A release etch process that results in etching away parts of the box layer 214 and the silicon oxide layer 430 is performed via a vapor hydrogen fluoride (VHF) process as shown in FIG. 5C. Alternatively, wet HF etching may be used. The VHF etching step is controlled so that the box layer 214 and silicon oxide layer 430 remains in areas where they are is still needed to connect other structures. These areas are typically wide enough to survive the VHF etch. The sacrificial blocks 540 and 548 may be dropped out as the box layer 214 attaching the blocks 540 and 548 to the device layer 210 is etched away. The oxide layer 430 is etched away to release a structure composed of the structure 526 and the two deep trench structures 514. Similarly, another structure composed of the structure 524 and the two shallow trench structures 512 is released. There may be some amount of oxide left since the extent of the etch by the VHF will be timed to keep some oxide after the etch.

The structures 410 and 510 have been removed via etching in area 502 to create another sacrificial block 550. This is performed with VHF, which removes oxide by a certain amount. Sacrificial blocks will be dropped during the etch. This may be used for instances where it is desired to create a large gap without having a very wide trench in the silicon. This is very useful around areas of lateral springs for example. The oxide layer 430 is also etched away from the top surface over the sacrificial block 550 to allow the sacrificial block 550 to be released. Similarly, the box layer 214 between the bond pad support structure 542 and the mirror support structure 544 is removed by etching. In area 502, the silicon oxide layer 430 attaching the two deep trench structures 514 is also etched away, thus forming a sacrificial block 552 between the structures 514. Parts of the box layer 214 remain to keep the bond pad structure 542 attached and the mirror support structure 544 attached to the device layer 210. FIG. 5D show the resulting structures in both areas 500 and 502 after the sacrificial blocks 540, 548, 550, and 552 are removed. This creates structures that have a wide gap between polysilicon features.

The structures in areas 500 and 502 are then inverted as shown in FIG. 5E. A metal coating layer is applied to the now top facing side of the structures 542 and 544 created from the handle layer 212. A mask is interposed over the handle layer 212. The mask includes apertures that allow the patterned deposition of the metal coating layer to the corresponding areas on the bond pad support structure 542 and the mirror support structure 544. This creates a bond pad 560 on the bond pad structure 542 and a mirror surface 570 on the mirror support structure 544. In this example, the metallic coating layer is Au/Cr or Au/Ti, where Cr and Ti are adhesion layers. Another example material for the coating layer may be multiple layers of index engineered dielectrics to enhance reflectivity.

As shown in FIG. 5E, the mirror support structure 544 forms the mirror structure 110 in FIG. 1 that is attached to the remaining structure of the device layer 210 between the polysilicon structures 512 that form the combs 152 and the body of the rotor 146. The stator 144 and corresponding combs 150 are formed from the structures 512. The power to the stator 144 is supplied through the bond pad structure 542. Alternatively, power may be supplied from other features such as a pad structure on top of the stator 144.

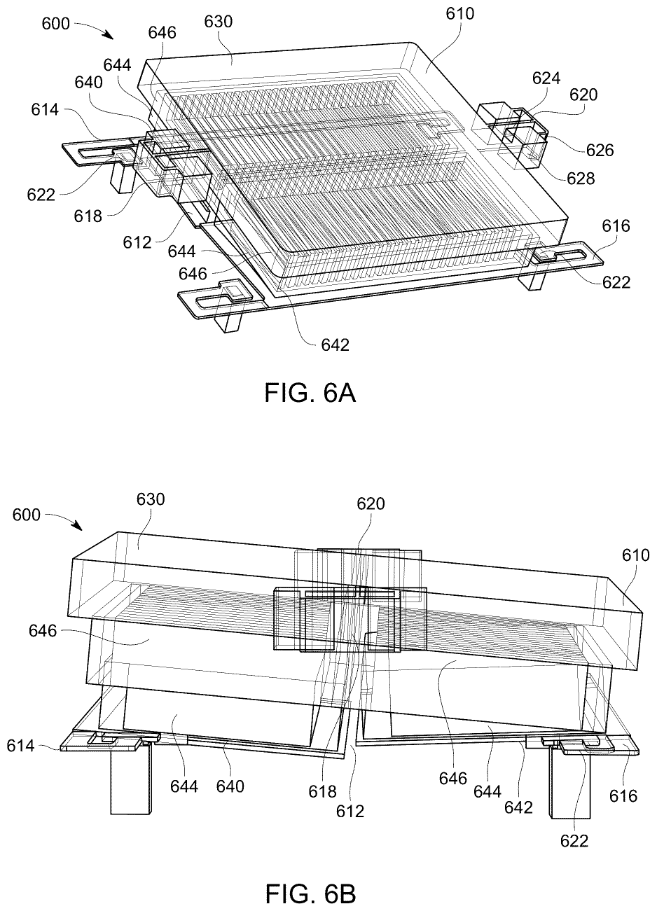

FIG. 6A is a see-through perspective view of another example MEMS mirror device 600. FIG. 6B is a side see-through perspective view of the example MEMS mirror device 600. The MEMS mirror device 600 has offset stators to enhance the movement range of a mirror structure 610. The example fabrication methods explained above allow the formation of the comb-based actuator mechanism 612 under the mirror structure 610. The MEMS mirror device 600 includes two conductor strips 614 and 616 with pads to allow connection to electrical contacts to power the actuator mechanism 612. The conductor strips 614 and 616 also function as flexures to allow displacement of the actuator structures of the actuator mechanism 612. Torsional anchor structures 618 and 620 are attached to the sides of the mirror structure 610 that allow the mirror structure 610 to rotate along the axis between the torsional support structures 618 and 620 that may be twisted to allow this motion. Each of the anchor structures 618 and 620 include a flexure 624 that is coupled to a T-shaped structure 626 with anchor blocks 628. The anchor blocks 628 may be attached to a base structure. The conductor strips 614 and 616 include pads 622 that allow electrical connections to provide power to the actuator mechanism 612. Anchor blocks are formed under the pads 622 to allow attachment to a base structure. The mirror structure 610 has a top surface 630 that constitutes a metallic reflective coating that serves as the mirror.

The example actuator mechanism 612 includes two comb-based actuators 640 and 642. Each of the actuators 640 and 642 includes a respective lower stator 644 and an upper rotor 646. In this example, the two rotors 646 are attached to the bottom of the mirror structure 610 opposite the top mirror surface 630. Thus, when one of the rotors 646 moves relative to the respective one of the stators 644, the mirror structure 610 may be twisted and thus moved to different angles relative to axis between the torsional structures 618 and 620. The rotor 646 is displaced in reference to the stator 644 by capacitive force created by applying power to the stator 644. The lower stators 644 have a main body with a series of fine comb teeth that are formed with the above described method of forming polysilicon fingers within trenches of the device layer. The corresponding rotors 646 have a main body that have a series of fine comb teeth that are formed by the device layer between the trenches.

In this example, the stator 644 is formed as an isolated polysilicon structure that is connected to a base of the device 600 on an interior edge via a hinge. Thus, the stators 644 are arranged in a V-shape relative to each other. The stator 644 is offset during the fabrication of the device 600 so it is tilted at an angle around the inner edge such that the opposite outer edge is raised. For example, the stator 644 may be set at the displacement angle via an anchor structure on the base that may hold the stator 644 at the displacement angle. The stator 644 may be moved into such position by a suitable tool during fabrication of the device 600. The offset angle of both stator 644 allows a greater degree of rotation of the mirror structure 610.

When one of the rotors 646 are lowered into the respective stator 644 by applying current to create electrostatic attractive force on the polysilicon comb teeth of the stator 644, the teeth of the rotors 646 interlace with the teeth of the stator 644. Thus, each of the comb teeth of the lower stator 644 are in proximity with corresponding comb teeth of the upper rotor 646. In the example shown in FIG. 6A-6B, power is applied to the stator 644 of the actuator 642. The corresponding rotor 646 is pulled toward the stator 646 by the resulting electrostatic force. As one half of the mirror structure 610 is attached to the rotor 644 of the actuator 642, one side of the mirror structure 610 is pulled down causing twisting around the torsional structures 618 and 620. The offset angled displacement of the stators 644 allows for a greater degree of rotation of the mirror structure 610 than the mirror structure 110 of the device 100 in FIG. 1C.

Specifically, for any vertical comb drive, a static offset is needed to generate quasistatic motion. For example, for a vertical comb drive where the stator and rotor are both 100 μm tall, if the initial static offset is 20 μm, the quasistatic range of operation is 20 μm, at which point the rotor and stator are perfectly aligned again, and therefore the net vertical force diminishes. A larger initial static offset means a large ranger for quasistatic operation as a result. For resonant, or AC operations however, the small, often hard to control offset due to intrinsic stress may be relied on to get the motion started and let the amplitude accumulate over time until the desired amplitude is reached.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

As used in this application, the terms “component,” “module,” “system,” or the like, generally refer to a computer-related entity, either hardware (e.g., a circuit), a combination of hardware and software, software, or an entity related to an operational machine with one or more specific functionalities. For example, a component may be, but is not limited to being, a process running on a processor (e.g., digital signal processor), a processor, an object, an executable, a thread of execution, a program, and/or a computer. By way of illustration, both an application running on a controller, as well as the controller, can be a component. One or more components may reside within a process and/or thread of execution, and a component may be localized on one computer and/or distributed between two or more computers. Further, a “device” can come in the form of specially designed hardware, generalized hardware made specialized by the execution of software thereon that enables the hardware to perform specific function, software stored on a computer-readable medium, or a combination thereof.

The terminology used herein is for the purpose of describing particular embodiments only, and is not intended to be limiting of the invention. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof, are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art. Furthermore, terms, such as those defined in commonly used dictionaries, should be interpreted as having a meaning that is consistent with their meaning in the context of the relevant art, and will not be interpreted in an idealized or overly formal sense unless expressly so defined herein.

While various embodiments of the present invention have been described above, it should be understood that they have been presented by way of example only, and not limitation. Although the invention has been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application. Thus, the breadth and scope of the present invention should not be limited by any of the above described embodiments. Rather, the scope of the invention should be defined in accordance with the following claims and their equivalents.

What is claimed is:

1. A method of fabricating a micro-electromechanical systems (MEMS) device, comprising:
providing a device layer, a handle layer, and a buried oxide layer between the handle layer and the device layer;
creating a top trench in a top surface of the device layer;
creating an oxide layer over the top surface of the device layer and the top trench;
coating the top of the device layer and the top trench with a first polysilicon layer;
etching away the oxide layer of the top trench or the top of the device layer to create an isolated structure from the first polysilicon layer; and
etching away areas of the handle layer and the buried oxide layer to create a support structure attached to the isolated structure.

2. The method of claim 1, wherein the top trench is a deep isolation trench extending through the device layer to the buried oxide layer, the method further comprising removing material of the device layer along the deep isolation trench to release the isolated structure.

3. The method of claim 1, wherein the top trench is a shallow breakup trench shallower than a thickness of the device layer.

4. The method of claim 1, wherein the oxide layer is a sacrificial layer of a specified thickness to form a capacitive gap of the specified thickness between the isolated structure and the device layer.

5. The method of claim 1, further comprising depositing a patterned metal layer on the support structure.

6. The method of claim 5, wherein the support structure is a mirror, and the patterned metal layer is patterned as the mirror.

7. The method of claim 5, wherein the support structure is a bond pad, and the patterned metal layer is patterned as an electrical contact.

8. The method of claim 1, wherein the isolated structure is a comb of a rotor of a comb actuator.

9. The method of claim 8, wherein the device layer bordering the isolated structure is a comb of a stator of the comb actuator.

10. The method of claim 1, wherein the device layer and the handle layer are fabricated from a crystalline material selected from one of a group of silicon, Gallium Arsenide (GaAs), Indium Phosphide (InP), and Silicon Carbide (SiC).

11. A method of fabricating a micro-electromechanical systems (MEMS) mirror comprising:
etching an isolation trench in a device layer formed on a buried oxide layer, and a handle layer;
etching a plurality of finger defining trenches in the device layer, wherein the plurality of finger defining trenches are parallel to the isolation trench;
growing an oxide layer to fill the isolation trench and coat sides of the finger defining trenches;
growing a polysilicon layer to fill the finger defining trenches;
removing the oxide layer coating sides of the finger defining trenches and the isolation trench to create a plurality of polysilicon fingers separated by a gap from a plurality of fingers of the device layer;
etching away areas of the handle layer and the buried oxide layer to define a support structure under the finger defining trenches;
etching away the oxide layer over the isolation trench to release the support structure and the finger defining trenches; and
metalizing a surface of the support structure to form a mirror surface.

12. The method of claim 11, wherein the device layer between the finger defining trenches form combs of a rotor of a comb actuator.

13. The method of claim 11, wherein the plurality of polysilicon fingers bordering the finger defining trenches form combs of a stator of the comb actuator.

14. The method of claim 13, further comprising:
forming a bond pad as part of a polysilicon conductor strip connected to the stator; and
forming part of the patterned metal layer as an electrical contact on the bond pad.

15. The method of claim 11, further comprising:
isolating a stator base on the device layer;
forming a hinge structure coupled to the stator base; and
displacing the stator base and the combs at an angle on the hinge structure to offset the combs of the stator from the combs of the rotor at the angle.

16. The method of claim 11, wherein the device layer and the handle layer are fabricated from a crystalline material selected from one of a group of silicon, Gallium Arsenide (GaAs), Indium Phosphide (InP), and Silicon Carbide (SiC).

17. A micro-electromechanical system (MEMS) device comprising:
an electrostatic actuator having a stator and a rotor;
a moveable structure having a bottom area coupled to the rotor, wherein the actuator is positioned under the moveable structure;
a base supporting the stator; and
a hinge coupled between the base and the moveable structure, wherein the actuator moves the moveable structure on the hinge.

18. The MEMS device of claim 17, wherein the moveable structure is a mirror.

19. The MEMS device of claim 18, further comprising another electrostatic actuator having a stator and a rotor coupled to the bottom area of the moveable structure, the another electrostatic actuator positioned under the moveable structure, wherein power is supplied to either actuator to move the moveable structure on the hinge.

20. The MEMS device of claim 17, wherein the stator is displaced at an angle from a planar surface of the base.
